(19) United States
(12) Patent Application Publication
(10) Pub. No.: US 2025/0160038 A1
(43) Pub. Date: May 15, 2025

(54) SOLAR CELL FABRICATION

(71) Applicant: NATIONAL UNIVERSITY OF SINGAPORE, Singapore (SG)

(72) Inventors: Jai PRAKASH, Singapore (SG); Shubham DUTTAGUPTA, Singapore (SG); Nitin NAMPALLI, Singapore (SG); Carlos Enrico Cobar CLEMENT, Singapore (SG)

(73) Assignee: NATIONAL UNIVERSITY OF SINGAPORE, Singapore (SG)

(21) Appl. No.: 18/715,527

(22) PCT Filed: Dec. 1, 2022
(86) PCT No.: PCT/SG2022/050876

§ 371 Date: May 31, 2024

(30) Foreign Application Priority Data
Dec. 1, 2021 (SG) 10202113353W

(51) Int. Cl. H10F 71/00; H01L 21/677; H01L 21/68; H10F 10/172; H10F 19/90

(52) U.S. Cl. CPC H10F 71/1375; H01L 21/67766; H01L 21/68; H10F 10/172; H10F 19/904

(57) ABSTRACT

Disclosed is a method for fabricating a solar module. The method involves providing a single processing tool (which may be a system) a plurality of tandem solar cells, electrically conductive adhesive (ECA) and a protective assembly. The tool produces an assembled lay-up of protected, interconnected, partially cured cells by forming a string by aligning the cells and applying ECA to both sides of the cells, placing the string on the protective assembly, and pre-curing the ECA at low temperature (80° C.-150° C.). Thereafter, external connections are formed, a protective assembly is applied to a second side of each cell, opposite the first side, and the lay-up is laminated to produce a solar module

### TECHNICAL FIELD

The present invention relates, in general terms, to interconnecting two-terminal (2T) tandem cells, a novel solar module design and method for laying up cells and electrically conductive adhesive (ECA) cell interconnections. More particularly, the present invention relates to a novel 2T tandem module fabrication process and tool facilitating that process.

### BACKGROUND

Standard wafer-based solar cell fabrication involves a thin slice of semiconductor, such as a crystalline silicon (c-Si), used for the fabrication of solar cells (photovoltaic cells). The wafer serves as the substrate for photovoltaic devices built in and upon the wafer. The wafer undergoes many fabrication processes, such as doping, ion implantation, etching, thin-film deposition of various materials, and patterning.

Each of the above techniques is well-understood and considered to be a standard design and fabrication method. As a result, standard tooling and systems can be used in standard wafer-based cell fabrication.

To increase the energy conversion efficiency of a solar cell, tandem solar cells have been more recently proposed. Fabrication of photovoltaic modules from tandem solar cells lack the standard tooling used in traditional single-junction silicon solar cells. Moreover, transferring partially finished cells between tools causes damage and misalignment of cells for subsequent module fabrication processes. Further, due to the fragile nature of materials used to fabricate tandem solar cells, temperatures and pressures typically applied to single-junction silicon solar cells during interconnection and module fabrication processes such as soldering and lamination may cause mechanical or thermal damage to the functional layers present in tandem solar cells.

It would be desirable to overcome or ameliorate at least one of the above-described problems with tandem module fabrication, or at least to provide a useful alternative.

### SUMMARY

The present invention relates to a tandem photovoltaic (PV) module. In particular, described herein is the interconnection of two-terminal (2T) tandem cells using a novel module design and method for laying up cells and cell interconnections using electrically conductive adhesive (ECA).

Disclosed is a method for fabricating a solar module, comprising:
providing, to a single processing tool:
   a plurality of tandem solar cells;
   electrically conductive adhesive (ECA); and
   a first protective assembly;
producing an assembled lay-up of protected, interconnected, partially cured cells by using the single processing tool to perform the steps of:
   forming a string by aligning the cells and applying ECA to both sides of cells; placing the string on the first protective assembly;
   pre-curing the ECA at low temperature in a range from 80° C.-150° C.;
   forming external connections;
applying a second protective assembly to a second side of each cell, opposite the first side; and
laminating the lay-up to produce a solar module.

The single processing tool may comprise at least one ECA dispenser, and applying ECA to both sides of each cell comprises:
applying ECA to a first side of each cell;
automatically flipping the string using a flipper; and
applying ECA to a second side of each cell opposite the first side.

Providing the first protective assembly may comprise providing one or both of a front layer and an encapsulant. The front layer may be glass. Providing one or both of a front layer and an encapsulant may comprise providing both of a front layer and an encapsulant.

Applying ECA to both sides of each cell may comprise applying ECA in a ribbon on each side. The single processing tool may comprise a line heater and pre-curing the ECA at low temperature comprises using the line heater to heat only the ribbon.

Applying the second protective assembly to a second side of each cell may comprise applying one or both of an encapsulant and rear cover.

Each cell may be a string and providing the plurality of cells thus may comprise cutting a full cell into a plurality of strings and providing the strings to the single processing tool.

Each cell of the plurality of cells may be a tandem solar cell.

Also disclosed is a single processing tool for use in fabricating solar module, comprising:
an electrically conductive adhesive (ECA) line comprising:
   at least one ECA printer for applying ECA to both sides of a string of cells; and
   an automatic cell flipper for flipping the cells after the at least one ECA printer has applied ECA to a first said side of the string, to facilitate application of ECA, by the at least one ECA printer, on a second said side of the string; and
a lay-up line comprising:
   one or more robotic arms for depositing cut ribbons on a protective assembly in the lay-up line, and for transferring the string from the ECA line onto the ribbons and protective assembly; and
   a line heater for pre-curing the ECA, by heating the ribbons.

The one or more robotic arms may comprise a first robotic arm for collecting and depositing the cut ribbons on the protective assembly, and a second robotic arm for transferring the string from the ECA line onto the ribbons and protective assembly.

The ECA line may further comprise a first transfer mechanism for moving the string beneath a first ECA printer of the at least one ECA printer for application of ECA to a first side of the string, and a second transfer mechanism for moving the string beneath a second ECA printer of the at least one ECA printer for application of ECA to a second side of the string. The first transfer mechanism and the second transfer mechanism may each be a conveyor.

The single processing tool may further comprise a robotic arm for transferring the string from the first transfer mechanism to the automatic cell flipper.

The automatic cell flipper may be hinged to the second transfer mechanism.

The single processing tool of claim 12, wherein the one or more robotic arms comprise at least one robotic arm for depositing the cut ribbons on the protective assembly in the lay-up line, and for transferring the string from the ECA line onto the ribbons and protective assembly, the at least one robotic arm moving in a first direction, the one or more robotic arms further comprising a robotic arm comprising the line heater and moving in a second direction perpendicular to the first direction to pre-cure the ECA.

Heating “only the ribbon” should be purposively construed to mean that there may be some residual heating in the vicinity of the ribbon, since heat radiates, but that heating should be substantially concentrated along the ribbon so as not to substantially affect the surrounding area of each cell.

Advantageously, the present disclosure provides a new cell lay-up and ECA curing process. The curing process reduces handling of cells after stringing. This is beneficial for tandem cells, minimising cell damage.

Advantageously, the present disclosure provides a new lay-up tool with a multiple cell holder using a single robotic arm, and a new pre-curing tool. These afford a high throughput process for 2T tandem cell interconnection and pre-curing.

Advantageously, embodiments provide low temperature interconnection processing and simultaneous lamination and curing. This enables processing temperatures in the range of 80-150° C., which minimizes thermal damage to the tandem solar cell. Moreover, curing is a 2-step process that helps reducing or minimising cell handling. Finally, the processes for the application of ECA and curing minimize mechanical pressure to the tandem solar cells. This avoids mechanical and thermal damage to the tandem solar cell and minimizes any degradation of performance due to such damage.

### BRIEF DESCRIPTION OF THE DRAWINGS

Embodiments of the present invention will now be described, by way of non-limiting example, with reference to the drawings in which:

FIG. 1 schematic of a 2-terminal (2T) tandem solar cell module;

FIG. 2 is the process flow for 2T Tandem module fabrication in an industrial environment, employing the present ECA based lay-up and stringing tool;

FIG. 3A illustrates the cutting process for producing cells for fabricating 2T tandem cells, and FIG. 3B shows the multiple cell holder of the robotic arm containing multiple cells;

FIG. 4 shows a single processing tool or system for assembling cells together;

FIG. 5 illustrates the ECA printing process;

FIG. 6 schematically illustrates a lay-up line tool;

FIG. 7 shows robotic arm A (first robotic arm) of the tool of FIG. 6;

FIG. 8 shows robotic arm B (second robotic arm) of the tool of FIG. 6; and

FIG. 9 shows robotic arm C (third robotic arm) of the tool of FIG. 6.

### DETAILED DESCRIPTION

Described below is a tandem photovoltaic (PV) module. The novel module design affords the interconnection of two-terminal (2T) tandem cell interconnections and avails itself of a new method for laying up cells and electrically conductive adhesive (ECA) cell interconnections.

Unlike standard wafer-based modules, there is no standard design and fabrication method/tool available for large-size 2T tandem (e.g. Perovskite/Silicon (Si)) modules. To realize a reliable tandem module, there are several issues with module design and fabrication methodologies (or tools) that need to be addressed. Described herein are concepts for improving the performance, reliability and fabrication of, for example, Si/perovskite based 2T tandem modules.

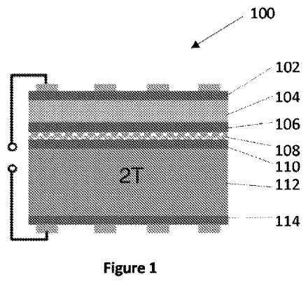

Tandem cells consist of a stack of two or more solar cells (‘sub-cells’) that are in intimate mechanical and electrical contact with each other. The sub-cells are a top sub-cell and a bottom sub-cell in the case of a two-junction tandem cell, and may consist of more than two sub-cells. Each sub-cell comprises one solar cell with a photovoltaic absorber material with a specific electronic bandgap capable of generating photovoltage from a specific spectral range present in sunlight. The specific spectral range for energy conversion in each sub-cell is unique and may overlap with the spectral range of the subsequent sub-cell-“subsequent” here refers to the other cells in the stack, e.g. for each cell in a two (or more) cell stack, the spectral range is unique and potentially overlaps (but may not overlap) the spectral range of the other cell (the subsequent cell or cells) in the stack. The mechanical, optical and electrical contact between sub-cells are formed using a suitable material or structure such as a transparent conductive adhesive, a tunnel junction or a recombination junction. A typical tandem solar cell consisting of two sub-cells is shown in FIG. 1.

The tandem solar cell 100 in FIG. 1 comprises two sub-cells. The first sub-cell comprises a wide bandgap absorber material 104 sandwiched between a n-type or n-doped semiconductor layer 102 and p-type or p-doped semiconductor layer 106. The second sub-cell comprises a lower or narrower bandgap absorber material 112 sandwiched between a n-type or n-doped semiconductor layer 110 and p-type or p-doped semiconductor layer 114. A recombination junction layer or layer stack 108 is sandwiched between the p-type layer 106 of the first sub-cell and the n-type layer 110 of the second sub-cell.

The differing bands of light absorbance result in the tandem cell being able to absorb, and convert to electrical energy, a broader range of wavelengths of sunlight.

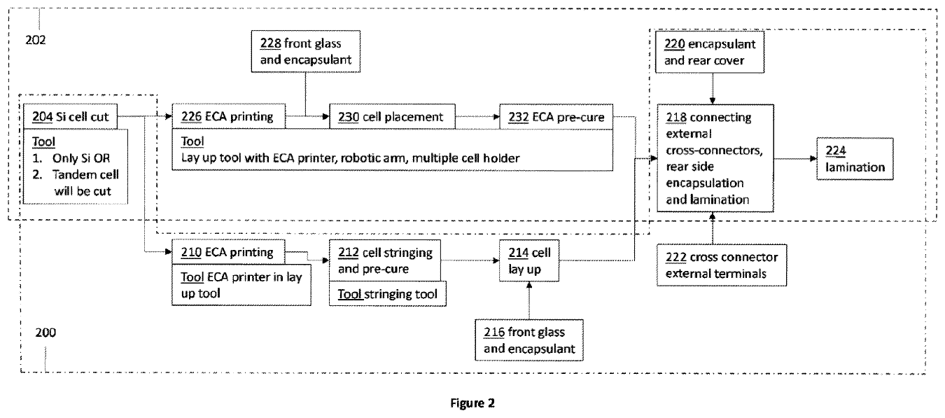

FIG. 2 shows an electrically conductive adhesive (ECA)-based standard process 200 (employing standard tooling) and the present process 202 (employing the present tool) for 2T tandem module fabrication and assembly.

The single processing tool performs the steps where methods 200, 202 deviate—i.e. steps, 226, 230 and 232, in which front glass provision and encapsulation 228 occurs prior to ECA pre-curing. The processes of cell-cutting (204), connecting cross-connectors (206) to external terminals and the lamination processes (208) are the same for standard process (200) as well as the new process (202), and will be known to the skilled person.

FIG. 2 schematically represents a variety of processes in each fabrication sequence—200, 202. The present methods focus predominantly on improving ECA printing on cells (step 226 in method 202, versus step 210 in method 200), automatic cell placement (step 230 in method 202) and ECA pre-cure (step 232 in method 202). In the method 202, steps 226, 230, and 232 are performed by a single tool. This single tool application facilitates high throughput commercial usage. It achieves this by avoiding transferal or handling of cells (manual or automatic) after attaching the interconnecting ribbons. Avoiding transferal or handling of cells reduces or avoids damage and misalignment of cells.

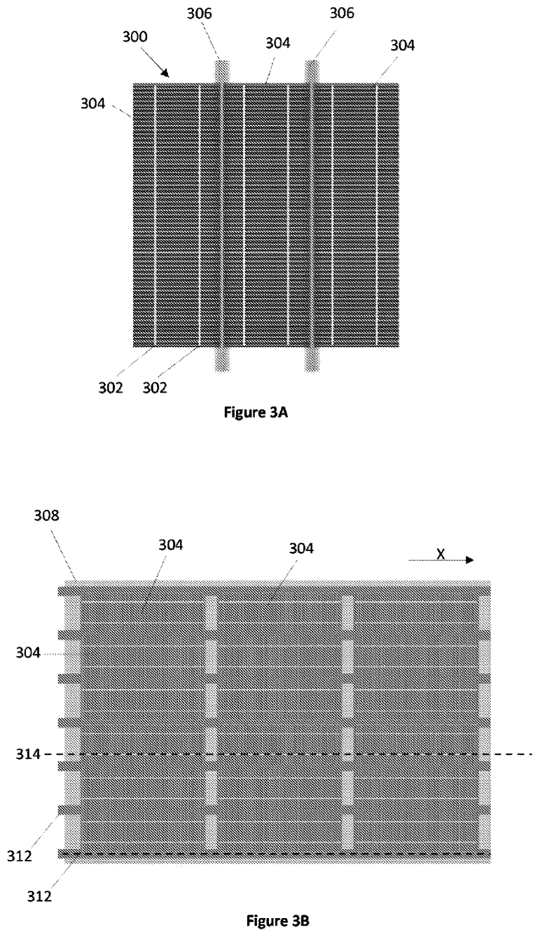

In the cutting step (204), as reflected in FIG. 3A, the Si solar cells (i.e. full cells) are cut into cells (hereinafter referred to as “cut cells” or tandem cells for ease of illustration) of the required size, along cut lines 306. Presently, the cut cells are of a size that fits into a holder of the multiple cell holder of the robotic arm (discussed below). With reference to FIG. 3A, each solar cell 300 is cut parallel to the bus bar(s), two of which are referenced by numeral 302. Each resulting cut cell 304 has two bus bars 302.

Any appropriate cutting process can be used, such as thermal laser separation (TLS) dicing, mechanical sawing or laser abrasion. In general, TLS dicing is preferred.

In the prior art method 200, after cutting, ECA is then printed or deposited (step 210). The purpose of ECA printing is to dispense an electrically conductive paste or ink that mechanically and electrically connects the cell busbars and the (tab) ribbons. ECA typically consists of metal particles suspended in an adhesive where it is usually deposited onto the cell through jet printing, screen printing or fluid dispensing. Printed ECA is applied evenly onto the busbars with no excess paste causing smearing. Furthermore, the ECA is applied in amounts sufficient to cause good adhesion for mechanical linking and low contact resistance for better electrical performance. Finally the ECA printing should have enough integrity to last over the life of the product and be resistant to thermal cycling and delamination.

In the prior art method 200, after ECA printing (step 210) the cells undergo stringing (step 212) and layup (step 214). In step 212, cell stringing refers to the physical and electrical interconnection of individual cells together to form a string. This is typically done by connecting the rear side of one cell to the front side of its adjacent cell using tab wire to form a series connection. Typically, cells are aligned using a robotic arm where cut pieces of wire tab are soldered directly onto the busbars at high temperatures (<200 C) with flux. The temperatures are necessary to melt the metallic SnPb coating on the tab which then adheres to the busbar forming an electrical connection. However, ECA based printing replaces soldering with a low temperature curing process (80-150 C) for more temperature sensitive cells. A pre-cure is performed after ECA printing to set the tabs in place and ensure enough mechanical linking for handling (step 212). After step 212, cells in the finished string should be evenly spaced and aligned, with the tabs positioned over the busbars and physically adhered to the cell.

Under step 214, cell lay-up refers to the placement of completed strings onto the module glass before it is finally laminated. A PV module will typically consist of 6-12 strings depending on the configuration. Completed strings are aligned either by hand or with robotic arms onto PV module glass. If done properly, a good cell lay-up will have consistent gaps between strings and enough space at the module edges for soldering cross connectors that lead to the external terminals.

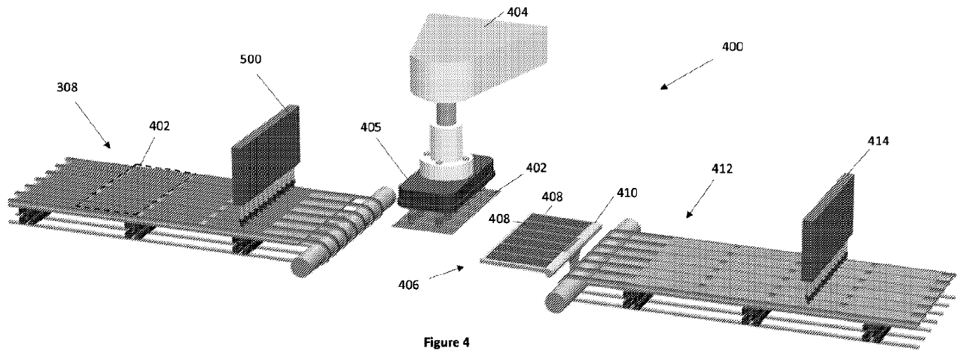

In the present method, once cut, the cut cells 304 are positioned onto transfer mechanism 308 of the single processing tool 400 shown in FIG. 4. The transfer mechanism 308 maintains a position of each cell 304 for ECA printing or deposition (step 226). After ECA printing on one side, using printing heads 502 of printer 500, the transfer mechanism 308 transfers the cells to a gripper 405 (see FIG. 4) for onward processing (e.g. ECA printing on the rear side by printer 414—the side opposite the front side on which ECA was printed by printer 500). The transfer mechanism may be a conveyor or similar.

The transfer mechanism 308 also comprises guides 312, disposed in parallel. Presently, the guides 312 are aligned parallel to the direction of travel X of the cells 304 on the transfer mechanism 308. In other embodiments, the guides, and thus the bus bars of the cells, may be aligned perpendicular to the direction of travel X. Each neighbouring pair of guides 312—i.e. any two guides 312 between which there is no other guide—is spaced apart by the width of the cut cells 304, in the dimension perpendicular to the busbars 302.

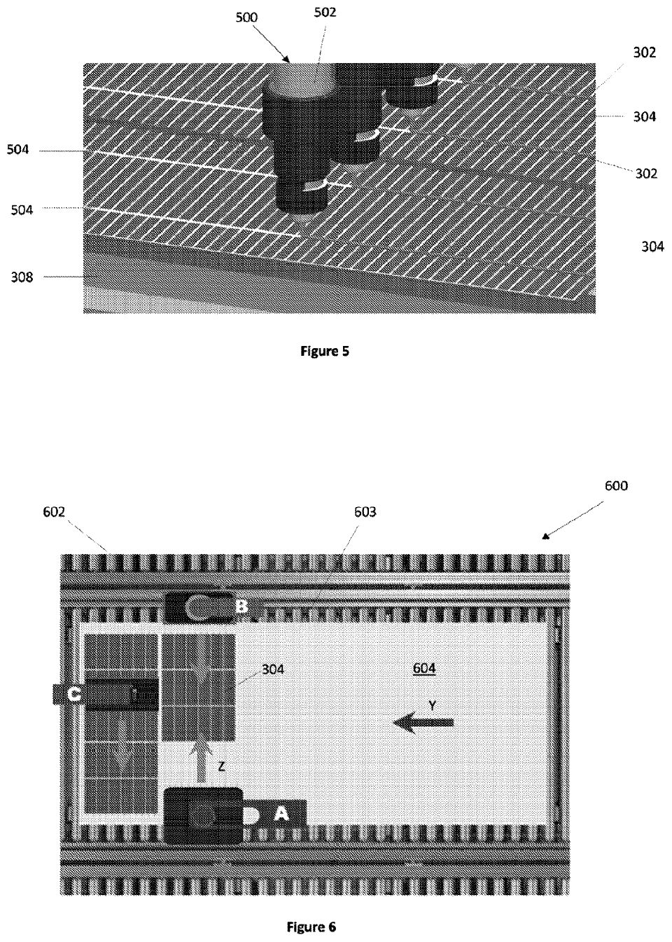

The transfer mechanism 308 forms part of a single processing tool 400 as shown in FIG. 4. The tool 400 also comprises an in-built or integrated ECA printer 500 (also referred to as a dispenser) reflected in FIG. 5. In FIG. 5, the transfer mechanism 308 maintains the cells 304 in register (alignment) with each other while the ECA printer 500 prints a line or lines of ECA 504 along bus bars 302. The ECA printer 500 may comprise a single ECA printer head 502 that is moved over each bus bar, or multiple printer heads as shown. In particular, the present ECA printer 500 comprises an ECA printer head 502 for each line 314 (see FIG. 3B) of aligned busbars—i.e. busbars 304, from neighbouring cells in the multiple cell holder. Each ECA printer head 502 deposits a line of ECA, preferably along the busbars.

If the transfer mechanism 308 is a conveyor, then the ECA printer heads 502 can remain stationary. This ensures that once the cells 304 are aligned on the transfer mechanism 308, the ECA printer heads 502 will print directly over busbars 302. In other embodiments, the ECA printer 500 may move along the busbars.

A string of cells (a “string” being generally indicated by box 402), after ECA printing, is transferred from the transfer mechanism 308 by a robotic arm 404. The robotic arm 404 may pick up the string 402 by any desired means, such as vacuum suction. To that end, the robotic arm 404 comprises a multiple cell gripper 405, for applying suction to the string 402 to pick up the cells.

The robotic arm 404 transfers the string 402 to a flipper 406. The flipper 406 flips the string 402 in its entirety. This ensures cells in each string 402 remain in alignment for depositing ECA on the rear surfaces of the cells using printer 414. The flipper 406 comprises a cell holder 408 for each cell in the string 402. The flipper 406 is hinged (at hinge 410) relative to a second transfer mechanism 412—e.g. a conveyor. Since the hinge 410 is fixed to the second transfer mechanism 412, the positions of the flipper 406 and second transfer mechanism 412 are fixed and consistent when the flipper places a string onto the second transfer mechanism 412. The string 402 in the flipper 406 will therefore be deposited in a consistent position on the second transfer mechanism 412.

To ensure the cells in the flipper 406 remain in position, the flipper 406 may comprise a vacuum suction system for applying suction to the cells to hold them to the flipper 406 as the flipper 406 flips the cells.

The second transfer mechanism 412 is used to assist with applying the ECA on the rear side (the front side being the side to which ECA is first applied and the rear side therefore being the side to which ECA is applied second). ECA is then applied to the rear side of the string 402 using ECA printer 414 in the same manner as performed by ECA printer 500.

The strings 402, with ECA printed on both front and rear sides, then leaves the ECA printing line (tool or system 400) for the lay-up line shown in FIG. 6.

The lay-up line 600 receives a protective assembly (228) presently comprising the front cover (hereinafter “front glass”) and encapsulant—e.g. ethylene-vinyl acetate (EVA) or polyolefin elastomer (POE) encapsulant solar film—in preparation for receiving the strings. The front glass simply refers to the first piece of glass placed on the cells, with the rear glass being the second piece of glass placed on the cells such that the first glass and second glass sandwich the cells between them. The front glass (with encapsulant) is positioned on the tool 602—e.g. on a transfer mechanism 603 of the tool 602, the transfer mechanism being any appropriate device such as a conveyor, though it may be replaced with a fixed plate or other stationary device—with the string (with ECA on both sides) being positioned on the front glass as discussed below. There is no restriction in the process requiring the front glass to be applied to the front side of the string and the rear glass being applied to the rear side of the string. The terms “front” and “rear” instead denote the order of application—i.e. first and second, respectively.

The lay-up line 600 comprises tool 602 into which the protective assembly (604) is loaded. In the tool 602, the protective assembly moves in a first direction Y, and one or more robotic arms move in a perpendicular axis Z to deposit ribbons and strings on the glass. This bidirectional movement speeds up the fabrication process, with the glass being moved in the Y axis each time a string is deposited onto the glass, or when a row or column of strings is deposited.

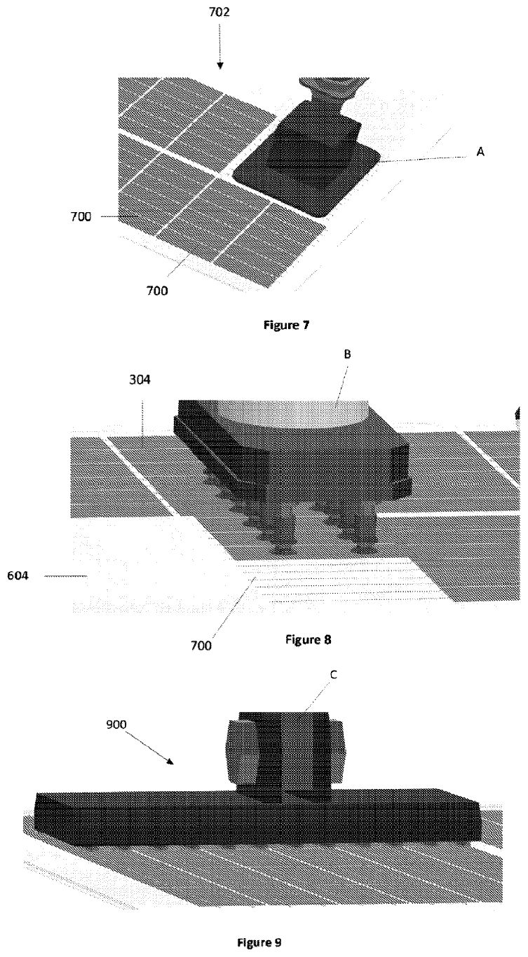

The present embodiment comprises three robotic arms A, B, C. With reference to FIG. 7, robotic arm A retrieves cut ribbons 700 from a store 702 of cut ribbons. Robotic arm A then positions the ribbons onto glass 604 by moving in the Z axis (bearing in mind that movement along an axis can be in both the positive and negative directions) over the front glass 604 while the front glass 604 remains stationary.

Robotic arm A may pick up ribbons through a vacuum suction system as with robotic arm 404, or any other mechanism.

Robotic arm B then retrieves a string 304 from the second transfer mechanism 412 of tool 400, or otherwise from the ECA printing line formed by tool 400, and deposits the string 304 on the cut ribbons as shown in FIG. 8. The cut ribbons 700 are now sandwiched between the string 304 and front glass 604. Again, robotic arm B may use vacuum suction or any other appropriate mechanism to pick up string 304 and deposit it onto the front glass 604.

Robotic arm B moves in the Z axis to deposit the string 304 onto the front glass 604. It then retreats along the Z axis to pick up another string.

After the string 304 is deposited by robotic arm B, the tool 600 advances the front glass 604 along Y axis. As the front glass 604 advances, it is moved under robotic arm C. Robotic arm C comprises a heater, such as line heater 900 as shown in FIG. 9, for pre-curing the EVA to hold the cells and ribbons in place. Robotic arm C, or the heater thereof, may apply a downward pressure to the string to hold it in place during heating or pre-curing. The heater 900 may also move along the front glass 604 along the Y axis. The line heater may comprise one or more long, thin heating elements that can be positioned parallel to a ribbon or ribbons, to heat an area including, or consisting of, the ribbon or ribbons to a greater extent than the area surrounding the ribbon or ribbons. In this way, the pre-curing temperature is kept low but delicate components of the device are not heated or are not heated to as high a temperature of the ribbon or ribbons. In essence, heating is selective.

The heater 900 comprises a heating element, presently an infrared coil, for each busbar being pre-cured at any one time. Notably, pre-curing is the first step in the curing process, with the second curing phase occurring at step 218.

Robotic arm C moves along the Y axis to pre-cure the cells of each string while robotic arm A lays the next set of cut ribbons and robotic arm B collects and lays the next string or strings onto the ribbons. Pre-curing occurs at low temperature—80° C. to 150° C. Preferably, the temperature is between 100-130 C, and more preferably 100-120 C

Thus, the single processing tool comprises tools 400 and 600, that receive as inputs cut cells, ECA, and a protective assembly (in which the encapsulant may be pre-applied, e.g. as a film, to the front glass). The single processing tool then outputs a partially cured lay-up of glass, encapsulant and interconnected cells.

A device, presently robotic arm C, holds the ribbon on to cells (ribbon holder) for partial curing. It does so by holding the strings placed by robotic arm B against the ribbons placed by robotic arm A, while heating an area comprising the ribbons.

The single processing tool provides for a new cell lay-up and ECA application process. An intention of the tool is to reduce handling of cells after stringing and/or connecting to ribbons. This is beneficial for thin cells in that it can reduce the opportunity for cell breakage.

After the lay-up is outputted from the single processing tool, it is combined with cross connector external terminals (222) to form external connections at step 218 in a known manner. Per step 220, a second protective assembly (220—generally comprising the rear glass and encapsulant) is applied to the second (e.g. rear where the first is the front) side of each cell, opposite the first side. Step 218 thus involves the soldering, either manual or automatic, of string ribbons onto the cross connectors followed by placement of rear side encapsulation and glass. After cell lay-up, cross connectors made from thicker wiring are laid over the ribbons and then soldered to form an electrical connection. The cross connectors, which carry the sum of currents from each string, are typically laid on the module edges and will lead out of the module and into the junction box which contains the external leads and bypass diodes. When done properly, cross-connector soldering introduces minimal resistive losses while holding strings in place. After this step, a layer of encapsulant is laid over the rear side of the cells, followed by either backsheet or glass to complete the module material. Step 218 thus involves connecting external cross-connectors. Cross connectors are wider and thicker than the ribbons placed by robotic arm A, but are nevertheless typically ribbons themselves, used to gather current from all the strings. Cross connectors are soldered from within the module but lead out onto external terminals and bypass diodes.

The lay-up is then laminated in a known manner at step 224 to produce a solar module. In the lamination step 224, the entire module is subjected to a high temperature press (140-165 C) to melt the encapsulant, fusing the layers of the module together. This is typically done with either a single-stage laminator or multiple stage laminator which allows for different heating and pressure parameters. Proper lamination is marked by the full cross-linking of encapsulant which leads to good mechanical adhesion of the different module layers. Furthermore, the absence of bubbles within the module indicates that the module lay-up was done properly and pressing and vacuum pressures are correctly set.

Embodiments of the technologies described herein facilitate significant improvement in cell open-circuit voltage, while maintaining good cell current and contactability resulting in improved solar cell efficiency. This is one of the major drivers towards reducing levelised cost of electricity (LCOE) required for large-scale PV installation and deployment.

It will be appreciated that many further modifications and permutations of various aspects of the described embodiments are possible. Accordingly, the described aspects are intended to embrace all such alterations, modifications, and variations that fall within the spirit and scope of the appended claims.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

The reference in this specification to any prior publication (or information derived from it), or to any matter which is known, is not, and should not be taken as an acknowledgment or admission or any form of suggestion that that prior publication (or information derived from it) or known matter forms part of the common general knowledge in the field of endeavour to which this specification relates.

1. A method for fabricating a solar module, comprising:
providing, to a single processing tool:
a plurality of tandem solar cells;
electrically conductive adhesive (ECA); and
a first protective assembly;
producing an assembled lay-up of interconnected, partially cured cells by using the single processing tool to perform the steps of:
forming a string by aligning the cells and applying ECA to both sides of the cells;
placing the string on the first protective assembly; and
pre-curing the ECA at low temperature in a range from 80° C.-150° C.;
forming one or more external connections on the string;
applying a second protective assembly to a second side of each cell, opposite first side; and
laminating the lay-up to produce the solar module.

2. The method of claim 1, wherein the single processing tool comprises at least one ECA dispenser, and applying ECA to both sides of each cell comprises:
applying ECA to the first side of each cell;
automatically flipping the string using a flipper; and
applying ECA to the second side of each cell opposite the first side.

3. The method of claim 1, wherein providing the first protective assembly comprises providing one or both of a front layer and an encapsulant.

4. The method of claim 3, wherein the front layer is glass.

5. The method of claim 3, wherein providing one or both of a front layer and an encapsulant comprises providing both of the front layer and the encapsulant.

6. The method of claim 1, wherein applying ECA to both sides of each cell comprises applying ECA in a ribbon on each side of each cell.

7. The method of claim 6, wherein the single processing tool comprises a line heater and pre-curing the ECA at low temperature comprises using the line heater to heat only the ribbon.

8. The method of claim 1, wherein applying the second protective assembly to a second side of each cell comprises applying one or both of an encapsulant and a rear cover.

9. The method of claim 1, wherein each cell is a full cell and providing the plurality of cells comprises cutting one or more the full cells into a plurality of cells of a required size, assembling the plurality of cells of the required size into strings and providing the strings to the single processing tool.

10. The method of claim 1, wherein each cell of the plurality of cells is a tandem solar cell.

11. A single processing tool for use in fabricating solar module, comprising:
an electrically conductive adhesive (ECA) line comprising:
at least one ECA printer for applying ECA to both sides of a string of cells; and
an automatic cell flipper for flipping the cells after the at least one ECA printer has applied ECA to a first said side of the string, to facilitate application of ECA, by the at least one ECA printer, on a second said side of the string; and
a lay-up line comprising:
one or more robotic arms for depositing cut ribbons on a protective assembly in the lay-up line, and for transferring the string from the ECA line onto the ribbons and protective assembly; and
a line heater for pre-curing the ECA, by heating the ribbons.

12. The single processing tool of claim 11, wherein the one or more robotic arms comprise a first robotic arm for collecting and depositing the cut ribbons on the protective assembly, and a second robotic arm for transferring the string from the ECA line onto the ribbons and protective assembly.

13. The single processing tool of claim 11- or 12, wherein the ECA line further comprises a first transfer mechanism for moving the string beneath a first ECA printer of the at least one ECA printer for application of ECA to the first side of the string, and a second transfer mechanism for moving the string beneath a second ECA printer of the at least one ECA printer for application of ECA to a second side of the string.

14. The single processing tool of claim 13, wherein the first transfer mechanism and the second transfer mechanism are each a conveyor.

15. The single processing tool of claim 13, further comprising a robotic arm for transferring the string from the first transfer mechanism to the automatic cell flipper.

16. The single processing tool of claim 13, wherein the automatic cell flipper is hinged to the second transfer mechanism.

17. The single processing tool of claim 12, wherein the one or more robotic arms comprise at least one robotic arm for depositing the cut ribbons on the protective assembly in the lay-up line, and for transferring the string from the ECA line onto the ribbons and protective assembly, the at least one robotic arm moving in a first direction, the one or more robotic arms further comprising a robotic arm comprising the line heater and moving in a second direction perpendicular to the first direction to pre-cure the ECA.
